(19) United States
(12) Patent Application Publication
(10) Pub. No.: US 2026/0081099 A1
(43) Pub. Date: Mar. 19, 2026

(54) ION IMPLANTATION DEVICE, MASK SET, AND METHOD FOR MANUFACTURING SEMICONDUCTOR DEVICE

(71) Applicant: Kioxia Corporation, Tokyo (JP)

(72) Inventor: Yasunori OHSHIMA, Yokkaichi (JP)

(73) Assignee: Kioxia Corporation, Tokyo (JP)

(21) Appl. No.: 19/079,741

(22) Filed: Mar. 14, 2025

(30) Foreign Application Priority Data
Sep. 19, 2024 (JP) 2024-162104

(51) Int. Cl. H01J 37/20; H01J 37/08; H01J 37/317; H01L 21/266

(52) U.S. Cl. CPC H01J 37/20; H01J 37/08; H01J 37/3171; H10P 30/22; H01J 2237/31711

(57) ABSTRACT

According to one embodiment, an ion implantation device includes an ion beam irradiation unit that emits an ion beam; a target substrate holding unit that holds a target substrate disposed in a path of the ion beam; a first mask holding unit that holds a first mask disposed in front of the target substrate in the path; and a second mask holding unit that holds a second mask disposed between the first mask and the target substrate in the path. The first mask includes a first opening pattern through which the ion beam is able to pass. The second mask includes a second opening pattern through which the ion beam is able to pass.

### CROSS-REFERENCE TO RELATED APPLICATION

This application is based upon and claims the benefit of priority from Japanese Patent Application No. 2024-162104, filed Sep. 19, 2024, the entire contents of which are incorporated herein by reference.

### FIELD

Embodiments described herein relate generally to an ion implantation device, a mask set, and a method for manufacturing a semiconductor device.

### BACKGROUND

In recent years, semiconductor devices such as three-dimensional memories are known.

### DESCRIPTION OF THE DRAWINGS

FIG. 1 is a schematic view for illustrating an example of a target substrate.

FIG. 2 is a schematic view for illustrating a first example of an ion implantation method.

FIG. 3 is a schematic view for illustrating a second example of an ion implantation method.

FIG. 4 is a schematic view for illustrating a warped shape of a semiconductor substrate.

FIG. 5 is a schematic view for illustrating a warped shape of the semiconductor substrate.

FIG. 6 is a schematic view for illustrating a warped shape of the semiconductor substrate.

FIG. 7 is a schematic view for illustrating a first example of a dose amount distribution.

FIG. 8 is a schematic view for illustrating a second example of the dose amount distribution.

FIG. 9 is a schematic view for illustrating a relationship between an ion beam and the target substrate.

FIG. 10 is a schematic view for illustrating a relationship between the ion beam and the target substrate.

FIG. 11 is a schematic view illustrating a first configuration example of an ion implantation device.

FIG. 12 is a schematic view illustrating the first configuration example of the ion implantation device.

FIG. 13 is a schematic view illustrating a second configuration example of the ion implantation device.

FIG. 14 is a schematic view illustrating the second configuration example of the ion implantation device.

FIG. 15 is a schematic view illustrating a configuration example of an ion beam receiving unit.

FIG. 16 is a schematic view illustrating a configuration example of the ion beam receiving unit.

FIG. 17 is a schematic view illustrating a structural example of a mask set.

FIG. 18 is a schematic view for illustrating an example of the ion implantation method and a method for manufacturing a semiconductor device.

FIG. 19 is a schematic view for illustrating an example of the ion implantation method and the method for manufacturing a semiconductor device.

FIG. 20 is a schematic view illustrating a modification example of the mask set.

FIG. 21 is a schematic view illustrating a modification example of the mask set.

FIG. 22 is a schematic view for illustrating an example of a method for conveying the target substrate after ion implantation.

FIG. 23 is a schematic view for illustrating an example of the method for conveying the target substrate after ion implantation.

### DETAILED DESCRIPTION

Embodiments provide to control the warpage of a semiconductor substrate.

In general, according to one embodiment, an ion implantation device includes: an ion beam irradiation unit that emits a ribbon-shaped ion beam; a target substrate holding unit that holds a target substrate disposed in a path of the ion beam; a first mask holding unit that holds a first mask disposed in front of the target substrate in the path; and a second mask holding unit that holds a second mask disposed between the first mask and the target substrate in the path. The first mask includes a first opening pattern through which the ion beam is able to pass. The second mask includes a second opening pattern through which the ion beam is able to pass.

Hereinafter, embodiments will be described with reference to the drawings. The relationship between the thickness and the plane dimensions of each element illustrated in the drawings, the ratio of the thicknesses of each element, and the like may differ from the actual relationship, ratio, and the like. Further, in the embodiments, substantially the same elements will be given the same reference numerals, and the description thereof will be omitted as appropriate.

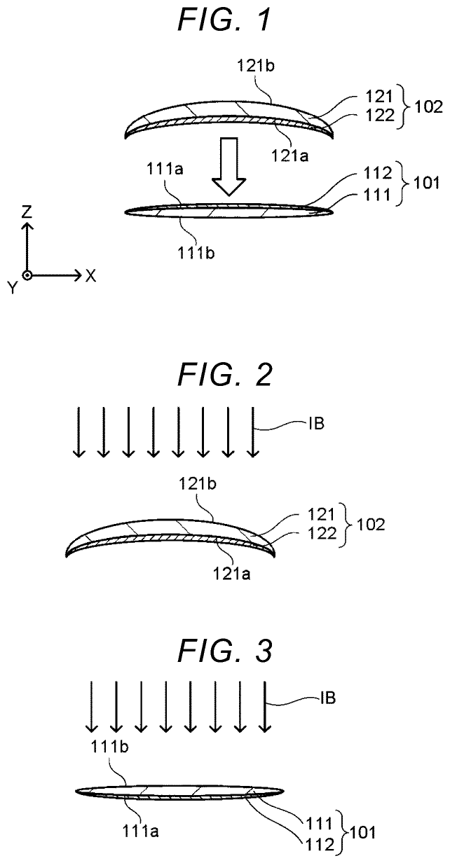

First, an example of a target substrate to which ions are implanted using an ion implantation device of the embodiment will be described. FIG. 1 is a schematic view for illustrating an example of the target substrate. FIG. 1 illustrates an X axis, a Y axis, and a Z axis. The X axis, the Y axis, and the Z axis intersect perpendicularly with each other.

Examples of the target substrates include semiconductor substrates used in semiconductor devices. The planar shape of the semiconductor substrate is, for example, circular. Examples of the semiconductor device include, but are not limited to, a NAND flash memory. A NAND flash memory can be manufactured, for example, by bonding a semiconductor substrate 101 and a semiconductor substrate 102 to each other as illustrated in FIG. 1. The semiconductor substrate 101 includes a semiconductor wafer 111 and a layer 112 formed on the semiconductor wafer 111. The semiconductor substrate 102 includes a semiconductor wafer 121 and a layer 122 formed on the semiconductor wafer 121. The X axis and the Y axis are, for example, the surface directions of the semiconductor substrate 101 and the semiconductor substrate 102. The Z axis is the thickness direction of the semiconductor substrate 101 or the semiconductor substrate 102.

The semiconductor wafer 111 includes a surface 111a on which a layer 112 is formed, and a surface (back surface) 111b opposite the surface 111a. The semiconductor wafer 111 is, for example, a silicon wafer. The layer 112 includes a peripheral circuit, including a CMOS circuit, for example in a NAND flash memory.

The semiconductor wafer 121 includes a surface 121a on which the layer 122 is formed, and a surface (back surface) 121b opposite the surface 121a. The semiconductor wafer 121 is, for example, a silicon wafer. The layer 122 includes a memory cell array, for example, in a NAND flash memory.

The surface of the layer 112 and the surface of the layer 122 are bonded to each other. Accordingly, the peripheral circuits and the memory cell array are electrically connected to each other.

A semiconductor substrate used in a semiconductor device may have warpage in at least one of the X-axis direction and the Y-axis direction, for example. For example, the semiconductor substrate 102 may have a larger warpage than the semiconductor substrate 101, a larger warpage along the X-axis direction than along the Y-axis direction, and a convex warpage from the surface 121a to the surface 121b. The warpage of a semiconductor substrate increases as the thickness or the number of layers formed on the surface of the semiconductor substrate increases, for example.

For example, in a case where the difference in warpage between semiconductor substrate 101 and semiconductor substrate 102 is large, when these substrates are bonded to each other, defects such as misalignment of the bonding position between semiconductor substrate 101 and semiconductor substrate 102 (so-called overlay anomaly) or the generation of unbonded portions at the end portions of the substrates may occur. Therefore, it is preferable to reduce the difference in warpage between the semiconductor substrate 101 and the semiconductor substrate 102 before bonding.

As a method for reducing the difference in warpage between the semiconductor substrate 101 and the semiconductor substrate 102, it is preferable to implant ions into at least a partial region of at least one of the semiconductor substrate 101 and the semiconductor substrate 102. In the region where the ions are implanted, the tensile or compressive stress of the semiconductor substrate changes. Accordingly, for example, the region with large tensile or compressive stress has smaller stresses, thereby reducing warpage. Examples of ions include arsenic ions, germanium ions, argon ions, boron fluoride ions, nitrogen ions, carbon ions, and boron ions.

FIG. 2 is a schematic view for illustrating a first example of an ion implantation method. In the first example of the ion implantation method, ions are implanted to reduce warpage of the semiconductor substrate. As illustrated in FIG. 2, an ion beam IB containing the above ions is selectively emitted onto a surface (back surface) 121b of the semiconductor wafer 121 to implant ions into the semiconductor wafer 121 to reduce warpage of the semiconductor substrate 102 in the X-axis direction. Accordingly, the warpage of the semiconductor substrate 102 is reduced, thereby making it possible to reduce the difference in warpage between the semiconductor substrate 101 and the semiconductor substrate 102.

FIG. 3 is a schematic view for illustrating a second example of the ion implantation method. In the second example of the ion implantation method, ions are implanted to intentionally increase the warpage of the semiconductor substrate. As illustrated in FIG. 3, ions are implanted into the semiconductor wafer 111 by selectively irradiating the surface (back surface) 111b of the semiconductor wafer 111 with the ion beam IB such that the warpage of the semiconductor substrate 101 in the X-axis direction becomes large. As a result, by forming the semiconductor substrate 101 with the same degree of warpage as the semiconductor substrate 102, the difference in warpage between the semiconductor substrate 101 and the semiconductor substrate 102 can be reduced.

The difference between the warpage in the X-axis direction and the warpage in the Y-axis direction of the semiconductor substrate such as the semiconductor substrate 101 or the semiconductor substrate 102 can be adjusted by forming a dose amount distribution of the ions by varying the implantation amount (dose amount) of the ions contained in the ion beam IB in the surface in accordance with the warped shape of the semiconductor substrate.

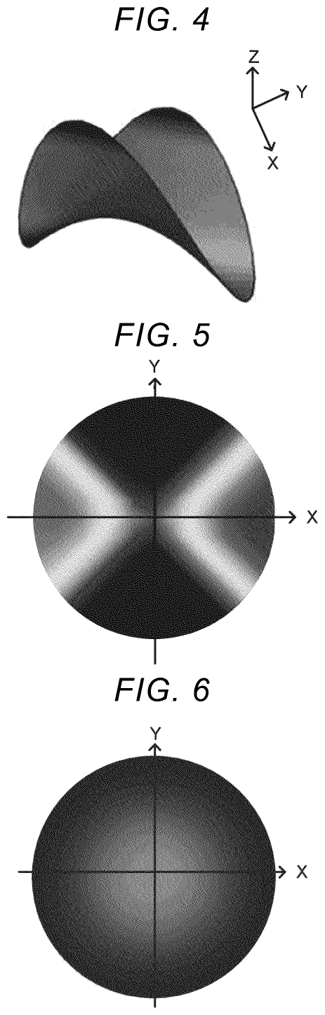

FIGS. 4, 5, and 6 are schematic views for illustrating the warped shape of the semiconductor substrate. FIGS. 4, 5, and 6 show the magnitude of warpage of the semiconductor substrate in the X-axis direction, the Y-axis direction and the Z-axis direction. FIGS. 4 and 5 show that the warpage in the X-axis direction passing through the center of the semiconductor substrate is larger than the warpage in the Y-axis direction passing through the center of the semiconductor substrate, and that the warpage is larger from the center of the semiconductor substrate toward both ends of the semiconductor substrate. In this case, it is preferable to form a dose amount distribution in which the dose increases from the center of the semiconductor substrate toward both ends in the X-axis direction. In order to reduce such warpage of the semiconductor substrate, a high dose amount of, for example, 1×10¹⁵ cm² or more is preferable. Alternatively, a dose amount distribution may be formed in which the dose amount decreases from the center of the semiconductor substrate toward both ends in the Y-axis direction. This makes it possible to adjust the warped shape of the semiconductor substrate to a shape (for example, a flat shape) with extremely little warpage in both the X-axis direction and the Y-axis direction, as illustrated in FIG. 6.

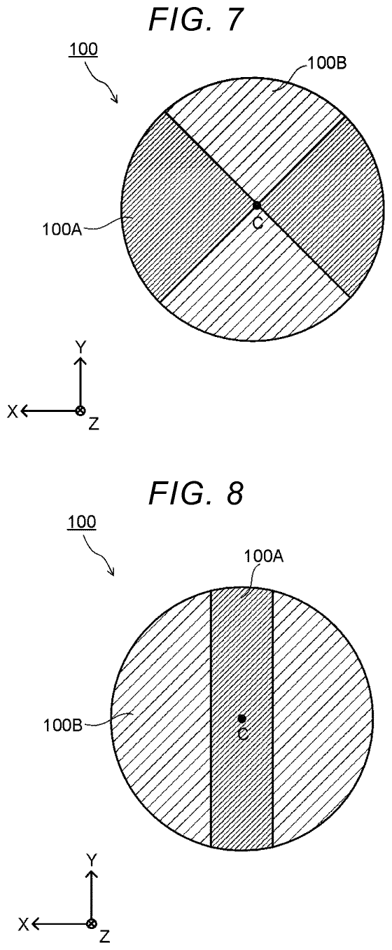

FIG. 7 is a schematic view for illustrating the first example of the dose amount distribution of the target substrate 100 which is the semiconductor substrate 101 or the semiconductor substrate 102. The back surface of the target substrate 100 has a high dose amount region 100A and a low dose amount region 100B. The X axis and Y axis are, for example, the surface directions of the target substrate 100. The Z axis is the thickness direction of the target substrate 100.

The high dose amount region 100A is a region where the dose amount is higher than that of the low dose amount region 100B. The high dose amount region 100A is provided, for example, in the X-axis direction, and extends to spread in a fan shape from the center C of the target substrate 100 toward the periphery of the target substrate 100. FIG. 7 illustrates a pair of high dose amount regions 100A. The pair of high dose amount regions 100A are disposed opposite to each other across the center C in the X-axis direction. By forming a pair of fan-shaped high dose amount regions 100A, the target substrate 100 including a convex warpage in the X-axis direction can be flattened. The dose amount in the high dose amount region 100A is preferably 1×10¹⁵/cm² or more. By setting the dose amount to 1×10¹⁵/cm² or more, the warpage of the target substrate 100 can be sufficiently adjusted.

The low dose amount region 100B is a region where the dose amount is lower than that of the high dose amount region 100A. The low dose amount region 100B is provided, for example, in the Y-axis direction, and extends to spread in a fan shape from the center C of the target substrate 100 toward the periphery of the target substrate 100. FIG. 7 illustrates a pair of low dose amount regions 100B. The pair of low dose amount regions 100B are disposed opposite to each other across the center C in the X-axis direction. The low dose amount region 100B may not contain the same type of ions as those implanted in the high dose amount region 100A.

FIG. 8 is a schematic view for illustrating a second example of the dose amount distribution on the target substrate 100. FIG. 8 differs from FIG. 7 at least in that the high dose amount region 100A is formed in a line shape passing through the center C in the Y-axis direction to separate the low dose amount region 100B. By forming the high dose amount region 100A in a line shape, for example, a convex warpage along the X-axis direction can be formed on the flat target substrate 100. For other details of the high dose amount region 100A, the description of the high dose amount region 100A in FIG. 7 can be used as appropriate.

FIG. 8 illustrates a pair of low dose amount regions 100B. The pair of low dose amount regions 100B are disposed opposite to each other in the X-axis direction with the high dose amount region 100A there between. For other details of the low dose amount region 100B, the description of the low dose amount region 100B in FIG. 7 can be used as appropriate.

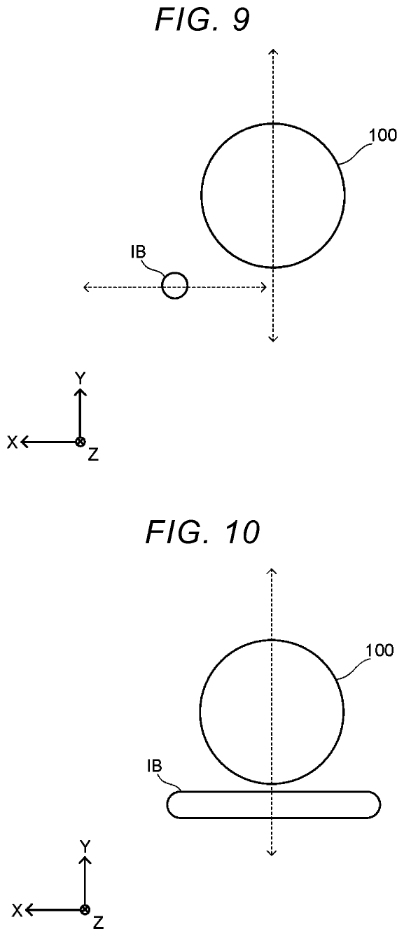

FIGS. 9 and 10 are schematic views for illustrating the relationship between the ion beam IB and the target substrate 100. FIGS. 9 and 10 schematically illustrate the target substrate 100 as viewed in a direction along the path of the ion beam IB. The X axis and Y axis are, for example, the surface directions of the target substrate 100. The Z axis is the thickness direction of the target substrate 100. FIGS. 9 and 10 illustrate the direction of movement of the ion beam IB and the target substrate 100 indicated by dashed arrows.

For example, in the case of a low dose amount of 1×10¹⁴/cm² or less, ion implantation can be performed using a spot-shaped ion beam IB. The spot-shaped ion beam IB can be scanned along the X-axis direction, and therefore, as illustrated in FIG. 9, by scanning the ion beam IB in the X-axis direction while scanning the target substrate 100, for example, in the Y-axis direction, the back surface of the target substrate 100 can be irradiated with the ion beam IB to perform ion implantation. In this case, it is easy to control the dose amount in the surface of the target substrate 100.

However, when a high dose amount of, for example, 1×10¹⁵/cm² or more is required, it is necessary to perform ion implantation using a ribbon-shaped ion beam IB. For example, in the case of a horizontally elongated ribbon-shaped ion beam IB, the ion beam IB is fixed at the same position without being scanned in the X-axis direction. Therefore, as illustrated in FIG. 10, the target substrate 100 can be scanned, for example, in the Y-axis direction without scanning the ion beam IB, thereby irradiating the back surface of the target substrate 100 with the ion beam IB to perform ion implantation. In this case, it is difficult to control the dose amount in the surface of the target substrate 100. Therefore, it becomes difficult to form the dose amount distribution as illustrated in FIG. 7 or 8. Alternatively, a method may be considered in which a mask including an opening pattern is formed on the back surface of the target substrate 100 using, for example, photolithography technology, and ions are implanted through the mask. However, in the above method, it is necessary to form different masks depending on the planar shape of the high dose amount region, which is desired to be formed, and thus the manufacturing cost increases.

Therefore, in the embodiment, a ribbon-shaped ion beam IB is selectively emitted onto the back surface of the target substrate 100 through a mask set combining a plurality of masks to perform ion implantation, thereby forming a dose amount distribution including the high dose amount region as illustrated in FIG. 7 or 8.

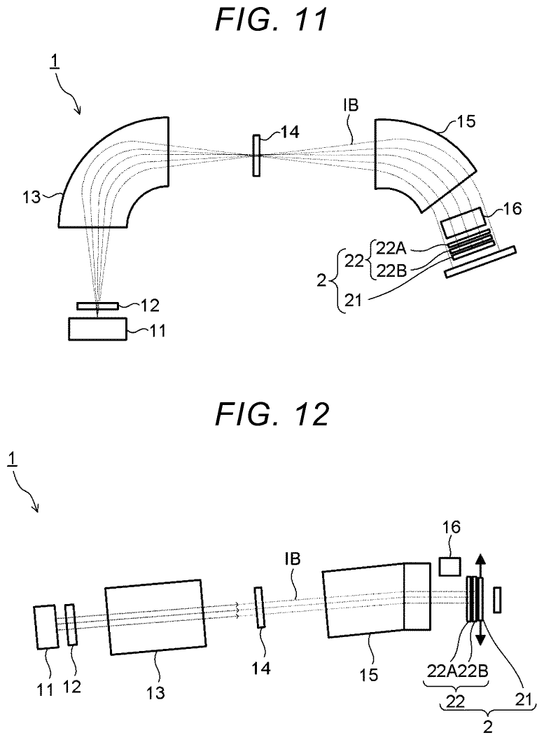

FIGS. 11 and 12 are schematic views illustrating a first configuration example of the ion implantation device according to the embodiment. The first configuration example is a configuration example of an ion implantation device capable of irradiating (e.g., configured to irradiate) the target substrate 100 with a horizontally elongated ribbon-shaped ion beam IB. FIG. 11 is a schematic view in the upper surface direction of a first configuration example of the ion implantation device. FIG. 12 is a schematic view in the side surface direction of the first configuration example of the ion implantation device.

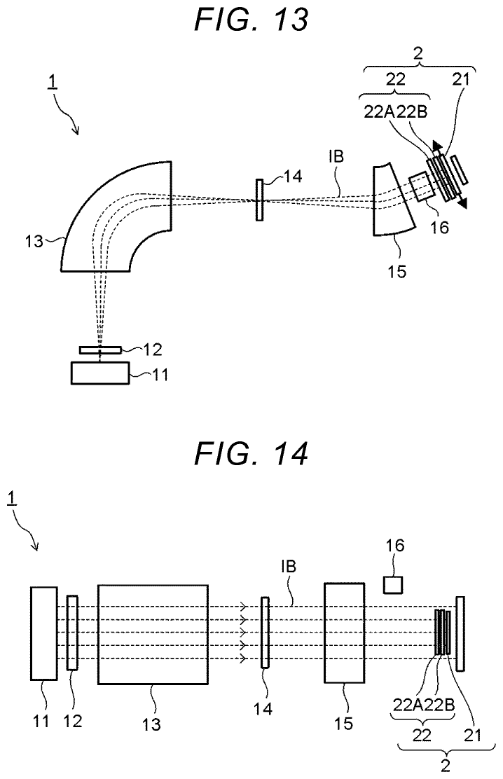

FIGS. 13 and 14 are schematic views illustrating a second configuration example of the ion implantation device according to the embodiment. The second configuration example is a configuration example of an ion implantation device capable of irradiating (e.g., configured to irradiate) the target substrate 100 with a vertically elongated ribbon-shaped ion beam IB. FIG. 13 is a schematic view in the upper surface direction of a second configuration example of the ion implantation device. FIG. 14 is a schematic view in the side surface direction of the second configuration example of the ion implantation device.

The ion implantation device includes an ion beam irradiation unit (irradiator) 1 (also referred to herein as “ion beam irradiation system 1”) and an ion beam receiving unit 2 (also referred to herein as “ion beam receiving unit system 2”). The irradiation unit 1 can be implemented a processing circuit including at least one processor or memory. The ion beam receiving unit 2 can be implemented a processing circuit including at least one processor or memory.

The ion beam irradiation unit 1 can generate the ion beam IB (e.g., emit ions along a defined trajectory). The ion beam irradiation unit 1 includes an ion source 11, an extraction electrode 12, an analyzer magnet 13, a mass slit 14, a collector magnet 15, and an electron neutralizer 16.

The ion source 11 is capable of generating (e.g., configured to generate) ions.

The extraction electrode 12 is capable of extracting (e.g., configured to extract) the ions generated in the ion source 11 to generate the ion beam IB.

The analyzer magnet 13 is provided after the extraction electrode 12 in the middle of the path of the ion beam IB. The analyzer magnet 13 generates a magnetic field and passes the ion beam IB through the magnetic field, thereby removing ions other than those including a predetermined mass and charge from the ion beam IB and outputting them to the mass slit 14.

The mass slit 14 selectively allows the ion beam IB from the analyzer magnet 13 to pass through and blocks a part of the ion beam IB, thereby constricting the ion beam IB.

In the first configuration example, the collector magnet 15 spreads the ion beam IB from the mass slit 14 in the horizontal direction, and accordingly, it is possible to change the shape of the ion beam IB into a horizontally elongated ribbon shape. In the second configuration example, the collector magnet 15 spreads the ion beam IB in the vertical direction, and accordingly, it is possible to change the shape of the ion beam IB into a vertically elongated ribbon shape. Examples of the collector magnet 15 include a magnetic field filter and an electric field filter.

The electron neutralizer 16 is disposed, for example, between the collector magnet 15 and a mask set holding unit (holder) 22 (also referred to herein as “mask set holding unit system 22”) in the middle of the path of the ion beam IB. The mask set holding unit 22 can be implemented as a processing circuit including at least one processor or memory.

The electron neutralizer 16 can generate a plasma to neutralize the positive charge in the ion beam IB. Examples of the electron neutralizers 16 include plasma flat guns (PFG).

The ion beam receiving unit 2 has a target substrate holding unit (holder) 21 (also referred to herein as “target substrate holding unit 21”)and the mask set holding unit 22. The target substrate holding unit 21 can be implemented a processing circuit including at least one processor or memory.

The target substrate holding unit (holder) 21 is disposed in the path of the ion beam IB and is capable of holding (e.g., configured to hold) the target substrate 100 to be irradiated with the ion beam IB.

The mask set holding unit (holder) 22 is disposed in front (e.g., upstream along the propagation path of the ion beam IB, between the ion beam irradiation unit 1 and the target substrate 100 along the propagation path of the ion beam IB, such that the ion beam IB passes through the mask set before reaching the target substrate 100) of the target substrate 100 held by the target substrate holding unit 21 in the path of the ion beam IB, and is capable of holding (e.g., configured to hold) the plurality of masks that can selectively pass through the ion beam IB. The mask set holding unit 22 includes, for example, a mask holding unit 22A and a mask holding unit 22B. The number of the plurality of masks is not particularly limited as long as the number is two or more.

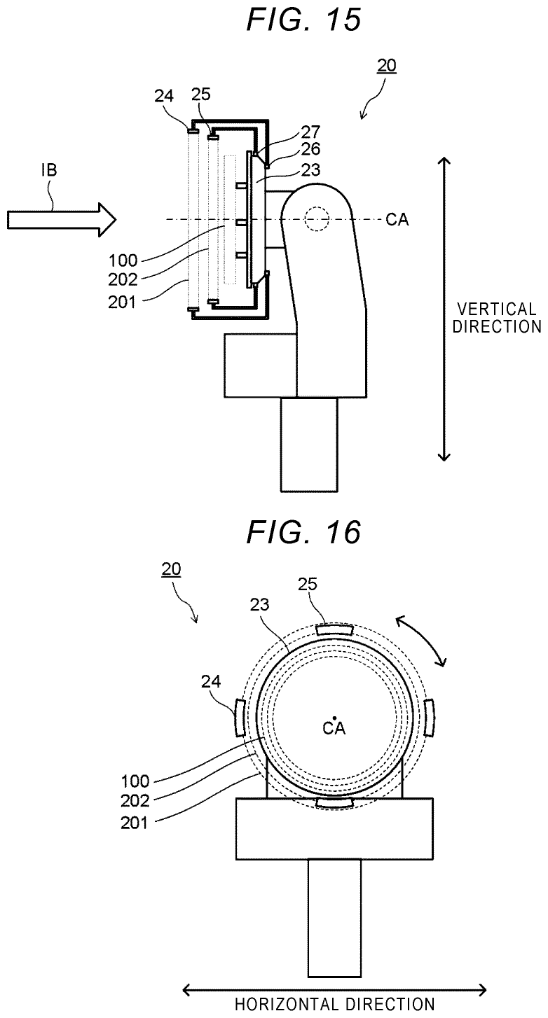

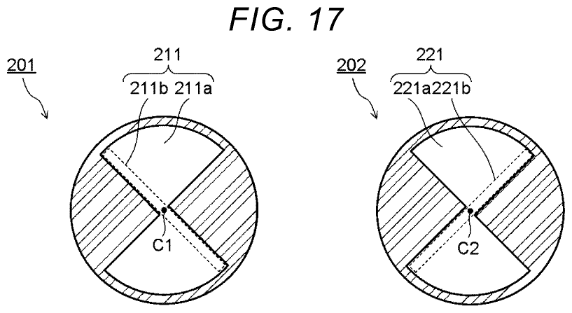

Next, a configuration example of the ion beam receiving unit 2 will be described. FIGS. 15 and 16 are schematic views illustrating the configuration example of the ion beam receiving unit 2. The target substrate holding unit 21, the mask holding unit 22A (e.g., first mask holding unit), and the mask holding unit 22B (e.g., second mask holding unit) are configured with a holding device 20, for example. FIG. 15 is a schematic view in the side surface direction (the direction parallel to the propagating direction of the ion beam IB) of the holding device 20. FIG. 16 is a schematic view in the front surface direction (the direction perpendicular to the propagating direction of the ion beam IB) of the holding device 20.

The holding device 20 has a stage 23, a fixture 24, a fixture 25, a rotation mechanism 26, and a rotation mechanism 27.

The stage 23 has a mounting surface on which the target substrate 100 is mounted. The mounting surface can be oriented between the vertical direction and the horizontal direction. The stage 23 may have a suction device capable of suctioning (e.g., configured to suction) the target substrate 100. Examples of suction devices include vacuum chucks. The stage 23 is capable of moving (e.g., configured to move) the target substrate 100 in both the vertical direction and horizontal direction. In the case of a horizontally elongated ion beam IB, the stage 23 may be scanned in the vertical direction. In the case of a vertically elongated ion beam IB, the stage 23 may be scanned in the horizontal direction. The stage 23 is rotatable about a rotation axis CA that is aligned with the propagating direction of the ion beam IB and the center of the mounting surface. The stage 23 can configure the target substrate holding unit 21.

The fixture 24 can fix a mask 201. The mask 201 is fixed by, for example, a plurality of fixtures 24. The fixture 24 is connected to the rotation mechanism 26 provided on the stage 23. The fixture 24 and the rotation mechanism 26 configure the mask holding unit 22A, and can rotate the mask 201 around the rotation axis CA. The mask holding unit 22A does not necessarily need to have a configuration that allows the mask 201 to rotate. The mask holding unit 22A can move the mask 201 in the vertical direction and horizontal direction in conjunction with the target substrate 100.

The fixture 25 can fix the mask 202. The mask 202 is fixed by, for example, a plurality of fixtures 25. The fixture 25 is connected to the rotation mechanism 27 provided on the stage 23. The fixture 25 and the rotation mechanism 27 configure the mask holding unit 22B, and can rotate the mask 202 around the rotation axis CA. The mask holding unit 22B does not necessarily need to have a configuration that allows the mask 202 to rotate. The mask holding unit 22B can move the mask 202 in the vertical direction and horizontal direction in conjunction with the target substrate 100.

In addition, in FIGS. 15 and 16, the size of the target substrate 100 is illustrated as being smaller than the size of the mask 201, and the size of the mask 202 is illustrated as being smaller than the size of the mask 201, but the sizes of the target substrate 100, the mask 201, and the mask 202 are not limited to this.

The operations of each element of the ion beam irradiation unit 1 and the ion beam receiving unit 2 may be controlled by a control device. The control device may be configured using hardware that uses, for example, a processor. It is noted that each operation may be stored as an operation program in a computer-readable recording medium such as a memory, and each operation may be executed by appropriately reading the operation program stored in the recording medium by the hardware.

FIG. 17 is a schematic view illustrating a structural example of the mask set. The mask set includes the mask 201 and the mask 202. FIG. 17 illustrates an example of the planar shape of the mask 201 and an example of the planar shape of the mask 202 when viewed from the propagating direction of the ion beam IB.

The mask 201 (e.g., first mask) can be held by the mask holding unit 22A. The mask 201 has a planar shape, for example, a circular shape. The mask 201 includes an opening pattern 211 including an opening 211a and an opening 211b. The mask 201 can selectively block the ion beam IB and selectively allow the ion beam IB to pass (e.g., through designated openings in the opening pattern 211, controlling the spatial distribution of the ion beam IB before it reaches downstream components) through the opening pattern 211.

The opening 211a preferably extends to spread in a fan shape from the center C1 of the mask 201 toward (e.g., radially outward along the mask surface) the periphery of the mask 201. The center C1 may overlap the center C or the rotation axis CA in the propagating direction of the ion beam IB. FIG. 17 illustrates a plurality of openings 211a, but the plurality of openings 211a is not particularly limited as long as the number is one or more. One of the plurality of openings 211a and another of the plurality of openings 211a may have a point-symmetric relationship with respect to the center C1.

The opening 211b is directly connected to the opening 211a and extends continuously from the opening 211a. The opening 211b preferably extends in a line shape passing through the center C1. Both ends in the length direction of the opening 211b may extend to the arc-shaped end portions of the plurality of openings 211a to separate the plurality of openings 211a.

The mask 202 (e.g., second mask) can be held by the mask holding unit 22B. The mask 202 has a planar shape, for example, a circular shape. The mask holding unit 22B can be configured to hold the mask 202 disposed between (e.g., downstream of the first mask 201 along the ion beam IB path, upstream of the target substrate 100) the first mask and the target substrate in the path. The mask 202 includes an opening pattern 221 including an opening 221a and an opening 221b. The mask 202 can selectively block the ion beam and selectively allow the ion beam to pass (e.g., through specific regions defined by the opening pattern 221, shaping the ion beam IB before it reaches the target substrate 100) through the opening pattern 221.

The opening 221a preferably extends to spread in a fan shape from the center C2 of the mask 202 toward (e.g., radially outward along the mask surface) the periphery of the mask 202. The center C2 may overlap the center C or the rotation axis CA in the propagating direction of the ion beam IB. FIG. 17 illustrates a plurality of openings 221a, but the number of openings 221a is not particularly limited as long as the number is one or more. One of the plurality of openings 221a and another of the plurality of openings 221a may include a point-symmetric relationship with respect to the center C2.

The opening 221b is directly connected to the opening 221a and extends continuously from the opening 221a. The opening 221b preferably extends in a line shape passing through the center C2. Both ends in the length direction of the opening 221b may extend to the arc-shaped end portions of the plurality of openings 221a to separate the plurality of openings 221a.

In the mask 201 and the mask 202, the planar shape of the opening pattern 211 and the planar shape of the opening pattern 221 preferably include a symmetric relationship. For example, it is preferable that the planar shape of the opening 211b and the planar shape of the opening 221b coincide with each other when rotated 90 degrees about the rotation axis CA that passes through the center C1 and the center C2.

The material of the mask 201 and the mask 202 is not particularly limited, but may be, for example, graphite. For example, the mask 201 and the mask 202 can be formed by processing a substrate such as a graphite plate to form desired opening patterns.

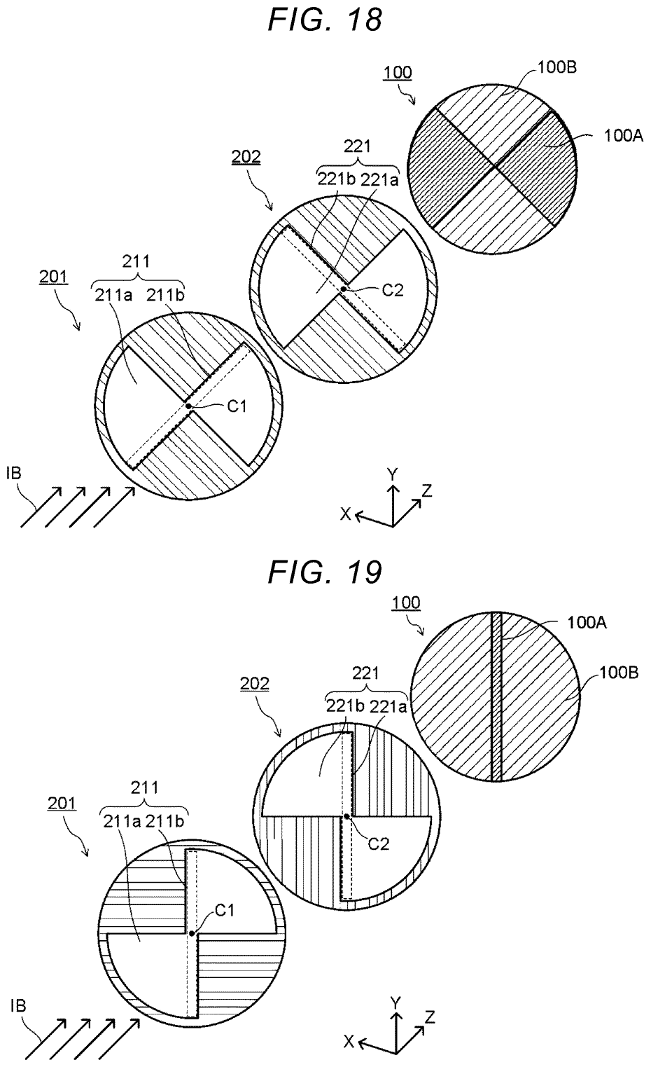

FIGS. 18 and 19 are schematic views for illustrating an example of an ion implantation method and a method for manufacturing a semiconductor device using the mask 201 and the mask 202. The X axis and Y axis are, for example, the surface directions of the target substrate 100. The Z axis is the thickness direction of the target substrate 100.

As illustrated in FIG. 7, when forming the fan-shaped high dose amount region 100A and the fan-shaped low dose amount region 100B on the back surface of the target substrate 100, at least one of the mask 201 and the mask 202 is rotated around the rotation axis CA, and as illustrated in FIG. 18, in the path of the ribbon-shaped ion beam IB, the opening 211a and the opening 221a overlap each other at the position where the high dose amount region 100A of the target substrate 100 is desired to be formed, and the opening 211b and the opening 221b are positioned to be rotated 90 degrees from each other, and then the ion beam IB is emitted. The ion beam IB passes through the opening 211a and the opening 221a and is irradiated onto the back surface of the target substrate 100. On the other hand, the ion beam IB is blocked by the mask 202 at least partially through the opening 211b, and the ion beam IB is blocked by the mask 201 at least partially through the opening 221b. Accordingly, it is possible to form the high dose amount region 100A and the low dose amount region 100B on the back surface of the target substrate 100. Without being limited to this, the high dose amount region 100A and the low dose amount region 100B may be formed by emitting the ion beam IB while rotating at least one of the mask 201 and the mask 202 such that the opening 211a and the opening 221a overlap each other at the position where the high dose amount region 100A of the target substrate 100 is desired to be formed in the path of the ribbon-shaped ion beam IB.

As illustrated in FIG. 8, when forming the line-shaped high dose amount region 100A on the back surface of the target substrate 100 to separate the low dose amount region 100B, at least one of the mask 201 and the mask 202 is rotated around the rotation axis CA, and as illustrated in FIG. 19, in the path of the ribbon-shaped ion beam IB, the opening 211b and the opening 221b overlap each other at the position where the high dose amount region 100A of the target substrate 100 is desired to be formed, and the opening 211a and the opening 221a are positioned to be rotated 90 degrees, and then the ion beam IB is emitted. The emitted ion beam IB passes through the opening 211b and the opening 221b and is irradiated onto the back surface of the target substrate 100. On the other hand, the ion beam IB is blocked by the mask 202 at least partially through the opening 211a, and the ion beam IB is blocked by the mask 201 at least partially through the opening 221a. Accordingly, it is possible to form the high dose amount region 100A and the low dose amount region 100B on the back surface of the target substrate 100. Without being limited to this, the high dose amount region 100A and the low dose amount region 100B may be formed by emitting the ion beam IB while rotating at least one of the mask 201 and the mask 202 such that the opening 211b and the opening 221b overlap each other at the position where the high dose amount region 100A of the target substrate 100 is desired to be formed in the path of the ribbon-shaped ion beam IB.

In the embodiment, the back surface of the target substrate 100 is selectively irradiated with the ion beam IB via a mask set including the mask 201 and the mask 202 to perform ion implantation. Accordingly, it is possible to selectively form the high dose amount region 100A in a partial region of the target substrate 100, even when forming a high dose amount region 100A of 1×10¹⁵/cm² or more that requires irradiation with a ribbon-shaped ion beam IB. Furthermore, by making the planar shape of each opening pattern of the mask 201 and the mask 202 a combination of a plurality of openings including different planar shapes (e.g., openings with varying geometries to modulate ion distribution, such as fan-shaped and line-shaped openings arranged to control dose distribution in distinct regions) and making at least one mask rotatable, a high dose amount region 100A including a plurality of shapes can be formed on the back surface of target substrate 100 using the same mask set. Accordingly, it is possible to improve the versatility of the ion implantation device.

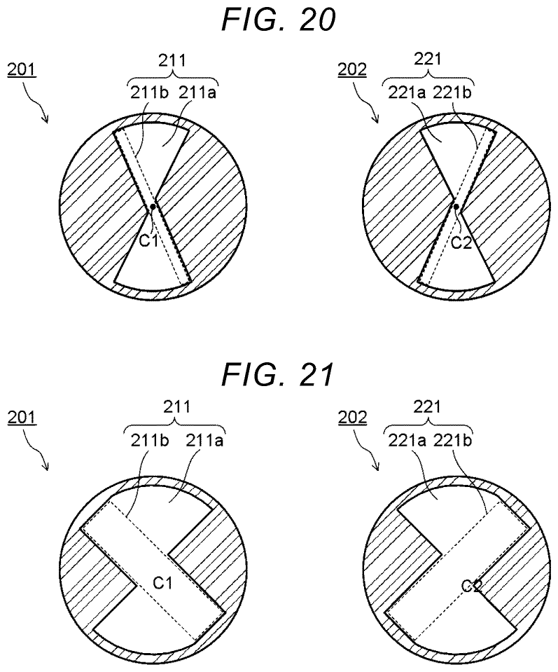

FIGS. 20 and 21 are schematic views illustrating a modification example of the mask set. FIGS. 20 and 21 illustrate a modification example of the planar shape of the mask 201 and a modification example of the planar shape of the mask 202.

When the planar shapes of the opening 211a and the opening 221a are fan-shaped, as illustrated in FIG. 20, the central angles of the opening 211a and the opening 221a can be changed as appropriate but are preferably 90 degrees or less. By setting the angle to 90 degrees or less, it is possible to easily form the high dose amount region 100A as illustrated in FIG. 7.

When the planar shapes of the opening 211b and the opening 221b are line-shaped, the widths of the opening 211a and the opening 221a can be changed as appropriate, as illustrated in FIG. 21. The widths of the opening 211a and the opening 221a are, for example, the lengths in the direction (short axis direction) perpendicular to the length direction (long axis direction) of the opening 211a and the opening 221a.

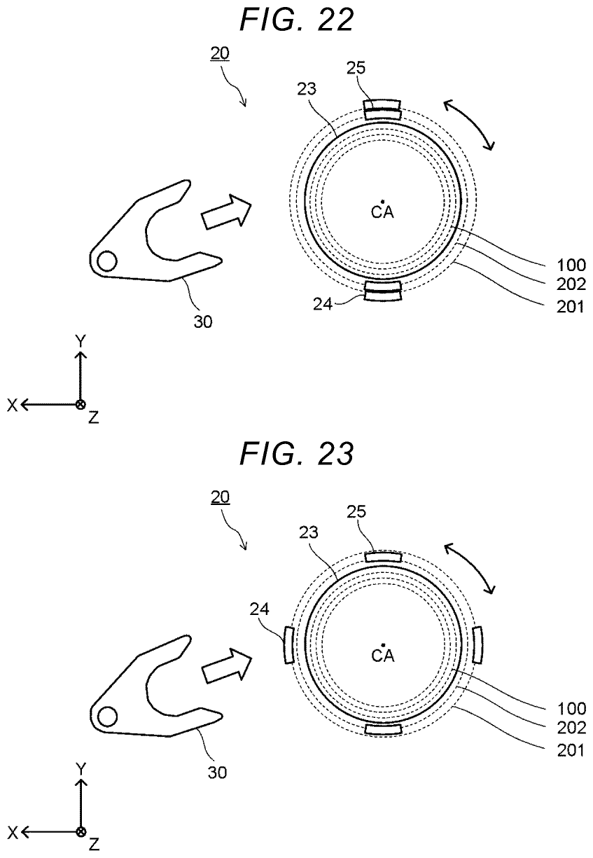

FIGS. 22 and 23 are schematic views for illustrating an example of the method for conveying the target substrate 100 after ion implantation. The X axis and Y axis are, for example, the surface directions of the target substrate 100. The Z axis is the thickness direction of the target substrate 100.

The target substrate 100 can be loaded and unloaded, for example, by a transfer arm 30 provided inside or outside the ion implantation device. During loading and unloading, the mounting surface of the stage 23 is oriented in the vertical direction. After ion implantation, it is preferable that the target substrate 100 be unloaded after at least one of the mask 201 and the mask 202 is rotated using at least one of the mask holding unit 22A and the mask holding unit 22B, and then the fixture 24 and the fixture 25 are returned to the initial positions such that the fixture 24 and the fixture 25 overlap each other in a straight line, as illustrated in FIG. 22. As illustrated in FIG. 23, when the fixture 24 and the fixture 25 do not overlap each other in a straight line, there is a possibility that the transfer arm 30 and the fixture 24 or the fixture 25 will interfere with each other, hindering removal of the target substrate 100.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. An ion implantation device comprising:
an ion beam irradiator that emits an ion beam;
a target substrate holder configured to hold a target substrate disposed in a path of the ion beam;
a first mask holder configured to hold a first mask disposed in front of the target substrate in the path; and
a second mask holder configured to hold a second mask disposed between the first mask and the target substrate in the path;
wherein the first mask includes a first opening pattern through which the ion beam is able to pass, and the second mask includes a second opening pattern through which the ion beam is able to pass.

2. The ion implantation device according to claim 1, wherein:
the first opening pattern and the second opening pattern have different planar shapes; and
at least one mask holder selected from a group configured with the first mask holder and the second mask holder is capable of rotating at least one mask selected from a group configured with the first mask and the second mask about a rotation axis along a propagating direction of the ion beam.

3. The ion implantation device according to claim 1, wherein:
the first opening pattern comprises a first opening extending in a fan shape from a center of the first mask toward a periphery of the first mask, and a second opening extending in a line shape to pass through the center of the first mask; and
the second opening pattern comprises a third opening extending in a fan shape from a center of the second mask toward a periphery of the second mask, and a fourth opening extending in a line shape to pass through the center of the second mask.

4. The ion implantation device according to claim 3, wherein:
the first opening pattern comprises a plurality of first openings; and
the second opening pattern comprises a plurality of third openings.

5. The ion implantation device according to claim 3, wherein:
a central angle of the first opening is 90 degrees or less;
a central angle of the third opening is 90 degrees or less; and
a planar shape of the first opening pattern and a planar shape of the second opening pattern comprise a symmetric relationship.

6. The ion implantation device according to claim 1, wherein:
the ion beam comprises at least one ion selected from a group configured with arsenic ions, germanium ions, argon ions, boron fluoride ions, nitrogen ions, carbon ions, and boron ions.

7. The ion implantation device according to claim 1, wherein:
the target substrate comprises:
a semiconductor wafer comprising a first surface and a second surface opposite the first surface; and
a layer formed on the first surface; and
the ion beam is emitted onto the second surface through the first mask and the second mask.

8. The ion implantation device according to claim 1, wherein:
the ion beam is ribbon-shaped.

9. A mask set disposed in front of a target substrate disposed in a path of an ion beam, the mask set comprising:
a first mask comprising a first opening pattern; and
a second mask comprising a second opening pattern, wherein:
the first opening pattern comprises:
a first opening extending in a fan shape from a center of the first mask toward a periphery of the first mask; and
a second opening extending in a line shape to pass through the center of the first mask;
the second opening pattern comprises:
a third opening extending in a fan shape from a center of the second mask toward a periphery of the second mask; and
a fourth opening extending in a line shape to pass through the center of the second mask; and
a planar shape of the first opening pattern and a planar shape of the second opening pattern comprise a symmetric relationship.

10. The mask set according to claim 9, wherein:
the first opening pattern and the second opening pattern have different planar shapes; and
at least one mask selected from a group configured with the first mask and the second mask is capable of rotating about a rotation axis along a propagating direction of the ion beam.

11. The mask set according to claim 9, wherein:
the first opening pattern comprises a plurality of first openings; and
the second opening pattern comprises a plurality of third openings.

12. The mask set according to claim 9, wherein:
a central angle of the first opening is 90 degrees or less;
a central angle of the third opening is 90 degrees or less.

13. The mask set according to claim 9, wherein:
the mask set is configured to selectively allow passage of at least one ion selected from a group configured with arsenic ions, germanium ions, argon ions, boron fluoride ions, nitrogen ions, carbon ions, and boron ions.

14. The mask set according to claim 9, wherein:
the mask set is disposed in front of a semiconductor wafer comprising a first surface and a second surface opposite the first surface; and
the ion beam is emitted onto the second surface through the first mask and the second mask.

15. The mask set according to claim 9, wherein:
the ion beam is ribbon-shaped.

16. A method for manufacturing a semiconductor device, comprising:
a target substrate comprising a semiconductor wafer comprising a first surface and a second surface opposite to the first surface and a layer formed on the first surface is disposed in a path of an ion beam, a first mask comprising a first opening pattern is disposed in front of the target substrate in the path, and a second mask comprising a second opening pattern is disposed between the first mask and the target substrate in the path;
the first opening pattern comprises:
a first opening extending in a fan shape from a center of the first mask toward a periphery of the first mask; and
a second opening extending in a line shape to pass through the center of the first mask;
the second opening pattern comprises:
a third opening extending in a fan shape from a center of the second mask toward a periphery of the second mask; and
a fourth opening extending in a line shape to pass through the center of the second mask;
a planar shape of the first opening pattern and a planar shape of the second opening pattern comprise a symmetric relationship; and
at least one mask selected from a group configured with the first mask and the second mask is rotated about a rotation axis along a propagating direction of the ion beam, and the second surface is selectively irradiated with the ion beam via the first mask and the second mask, thereby forming a dose amount distribution of ions contained in the ion beam on the semiconductor wafer.

17. The method for manufacturing the semiconductor device according to claim 16, wherein:
by selectively irradiating the second surface with the ion beam:
a first region and a second region are formed on the second surface, wherein:
the first region extending in a first direction passing through a center of the second surface and comprising a first dose amount of the ions;
the second region extending in a second direction passing through the center of the second surface and perpendicular to the first direction, and comprising a second dose amount of ions higher than the first dose amount.

18. The method for manufacturing the semiconductor device according to claim 17, wherein:
the second region extends in a fan shape from the center of the second surface toward a periphery of the second surface.

19. The method for manufacturing the semiconductor device according to claim 17, wherein:
the second region extends in a line shape to pass through the center of the second surface.

20. The method for manufacturing the semiconductor device according to claim 16, wherein:
the ion beam is ribbon-shaped.
